(19) United States
(12) Patent Application Publication
(10) Pub. No.: US 2024/0276756 A1
(43) Pub. Date: Aug. 15, 2024

(54) DISPLAY PANEL, MANUFACTURING METHOD THEREOF AND DISPLAY APPARATUS

(71) Applicants: Beijing BOE Technology Development Co., Ltd., Beijing (CN); BOE TECHNOLOGY GROUP CO., LTD., Beijing (CN)

(72) Inventors: Zhigao LU, Beijing (CN); Yichi ZHANG, Beijing (CN); Hui GUO, Beijing (CN)

(21) Appl. No.: 18/570,144

(22) PCT Filed: Aug. 24, 2022
(86) PCT No.: PCT/CN2022/114545

§ 371 Date: Dec. 14, 2023

(30) Foreign Application Priority Data
Oct. 11, 2021 (WO) PCT/CN2021/123006

(51) Int. Cl. H10K 50/17; H10K 50/15; H10K 71/12; H10K 71/60; H10K 102/00

(52) U.S. Cl. CPC H10K 50/171; H10K 50/15; H10K 71/12; H10K 71/60; H10K 2102/351

(57) ABSTRACT

A display panel (100), a method for manufacturing a display panel and a display apparatus are provided. The display panel (100) includes a first electrode layer (2), an electron transport layer (3), a light emitting layer (4), a hole transport layer (5), a hole injection layer (6) and a second electrode layer (7), which are sequentially stacked; a material of the hole injection layer (6) includes a first metal oxide and a second metal oxide, the first metal oxide and the second metal oxide each include a first metal element, and an outermost electron number of the first metal element in the first metal oxide is different from that of the first metal element in the second metal oxide. That is, the valences of the first metal element in the two metal compounds are different from each other, so that the hole injection capability is improved.

### TECHNICAL FIELD

The present disclosure relates to the field of display technology, and in particular to a display panel, a method for manufacturing a display panel and a display apparatus.

### BACKGROUND

Quantum dot light emitting diodes (QLEDs) have advantages of high color gamut, high color purity, wide viewing angle, long service life, high light emitting efficiency, and the like, and exhibit a great potential in the field of display technology, and thus become a favorable competitor for the next generation of display technology. One of the major problems faced by the quantum dot light emitting diode is the imbalanced carrier injection of the device at present.

A structure of a typical QLED device includes a cathode, an electron transport layer, a quantum dot light emitting layer, a hole transport layer, a hole injection layer and an anode which are stacked sequentially. An interface between a current commonly used material of the hole injection layer and the anode has an excessive energy level barrier, so that the problem of a low hole-injection rate still exists.

### SUMMARY

Embodiments of the present disclosure provide a display panel, a method for manufacturing a display panel and a display apparatus.

The present disclosure provides a display panel, including: a first electrode layer, an electron transport layer, a light emitting layer, a hole transport layer, a hole injection layer, and a second electrode layer, which are sequentially stacked sequentially; where a material of the hole injection layer includes a first metal oxide and a second metal oxide, the first metal oxide and the second metal oxide each include a first metal element, and an outermost electron number of the first metal element in the first metal oxide is different from that of the first metal element in the second metal oxide.

In some embodiments, the outermost electron number of the first metal element in the first metal oxide is a, the outermost electron number of the first metal element in the second metal oxide is b, and 0<a<b<8; and the first metal element in the first metal oxide accounts for 40% to 50% of a total amount of the first metal element, and the first metal element in the second metal oxide accounts for 50% to 60% of the total amount of the first metal element.

In some embodiments, the material of the hole injection layer further includes a metal M and a third metal oxide MOy, 0<y≤3, y being a natural number or a decimal.

In some embodiments, a mass sum of the metal M and the third metal oxide Moy is less than that of the first metal oxide and the second metal oxide.

In some embodiments, a mass ratio of the metal M to the third metal oxide MOy is in a range from 3:1 to 5:1.

In some embodiments, a mass percent of the metal M in the hole injection layer is in a range from 5% to 10%; a mass percent of the third metal oxide MOy in the hole injection layer is in a range from 1% to 5%.

In some embodiments, the hole injection layer includes a first sub-layer and a second sub-layer and a first reaction layer between the first sub-layer and the second sub-layer which are stacked together,; a material of the first sub-layer includes the first metal oxide, a material of the second sub-layer includes the metal M, and a material of the first reaction layer includes the second metal oxide and the third metal oxide MOy.

In some embodiments, the hole injection layer further includes n third sub-layers and n third reaction layers alternately arranged between the second sub-layer and the second electrode layer, and made of different materials; every one third sub-layer and one third reaction layer form a pair; the third reaction layer in each pair is closer to the second sub-layer than the third sub-layer in the pair, and n≥0 and n is an integer.

In some embodiments, a material of each third sub-layer includes a metal and a metal oxide, and is different from a material of the first sub-layer and a material of the second sub-layer; a material of each third reaction layer includes a metal oxide and is different from a material of the first reaction layer.

In some embodiments, the n third sub-layers are made of different materials and the n third reaction layers are made of different materials.

In some embodiments, the first reaction layer has a roughness less than that of the first sub-layer; and each third reaction layer has a roughness less than that of each third sub-layer.

In some embodiments, a metal element in the first metal oxide has a chemical activity lower than that of the metal M.

In some embodiments, the first reaction layer is a product of an oxidation-reduction reaction between the first sub-layer and the second sub-layer, the third reaction layer sandwiched between any two third sub-layers is a product of an oxidation-reduction reaction between the two third sub-layers, and the third reaction layer closest to the second sub-layer is a product of an oxidation-reduction reaction between the second sub-layer and the third sub-layer adjacent to the third reaction layer closest to the second sub-layer.

In some embodiments, the metal element in the first metal oxide includes at least one of molybdenum, vanadium, and tungsten.

In some embodiments, the metal M includes at least one of magnesium, aluminum, copper, and silver.

In some embodiments, one of the first electrode layer and the second electrode layer is a cathode and the other is an anode, and a material of each of the first electrode layer and the second electrode layer includes at least one of silver, aluminum, indium tin oxide, and carbon nanotube.

In some embodiments, a thickness ratio of the first sub-layer to the second sub-layer is in a range from 2:1 to 10:1.

In some embodiments, the first sub-layer has a thickness in a range from 5 nm to 10 nm, the second sub-layer has a thickness in a range from 1 nm to 5 nm, and the first reaction layer has a thickness in a range from 1 nm to 2 nm.

In some embodiments, the first reaction layer has a carrier mobility greater than that of the first sub-layer.

In some embodiments, the hole injection layer has a thickness in a range from 5 nm to 31 nm.

The present disclosure further provides a display apparatus, which includes the display panel.

The present disclosure further provides a method for manufacturing a display panel, including: providing a substrate, and sequentially forming a first electrode layer, an electron transport layer, a light emitting layer, a hole transport layer, a hole injection layer and a second electrode layer on the substrate, to form a light emitting element; a material of the hole injection layer includes a first metal oxide; a material of at least one of the hole injection layer and the second electrode layer includes a metal M; and applying a preset condition to the light emitting element, so that the first metal oxide and the metal M undergo an oxidation-reduction reaction, thereby forming at least a second metal oxide in the hole injection layer; the first metal oxide and the second metal oxide each contain a first metal element, and an outermost electron number of the first metal element in the first metal oxide is different from an outermost electron number of the first metal element in the second metal oxide.

In some embodiments, the preset condition includes: applying a voltage between the first electrode layer and the second electrode layer, the voltage is an operating voltage of the display panel.

In some embodiments, the preset condition includes: performing an ultraviolet irradiation treatment on the light emitting element, ultraviolet light used in the ultraviolet irradiation treatment has a wavelength in a range from 350 nm to 410 nm, and an energy between 0.84 J/cm² and 3 J/cm².

In some embodiments, the forming the hole injection layer includes: depositing the first metal oxide and the metal M on the hole transport layer by co-evaporation.

In some embodiments, the forming the hole injection layer includes: depositing the metal M on the hole transport layer by spin coating, the metal M being a metal nanowire; and depositing the first metal oxide on a side of the metal M away from the hole transport layer by spin coating.

### BRIEF DESCRIPTION OF DRAWINGS

The accompanying drawings, which are provided for further understanding of the present disclosure and constitute a part of this specification, are for explaining the present disclosure together with the detail description of embodiments, but are not intended to limit the present disclosure. In the drawings:

FIG. 1 is a schematic diagram of a structure of a display panel according to exemplary embodiments of the present disclosure.

FIG. 2a is a schematic diagram of a structure of a hole injection layer in the embodiments of FIG. 1.

FIG. 2b is a schematic diagram of another structure of a hole injection layer in the embodiments of FIG. 1.

FIG. 3 is a schematic diagram of a structure of a display panel according to exemplary embodiments of the present disclosure.

FIG. 4 is a schematic diagram of a structure of a first reaction layer in the embodiments of FIG. 3.

FIG. 5 is a schematic diagram of a structure of a display panel according to exemplary embodiments of the present disclosure.

FIG. 6 is a schematic diagram illustrating an example where a hole injection layer includes a plurality of sub-layers and a plurality of reaction layers in the embodiments of FIG. 5.

FIG. 7 is a schematic diagram of a structure of a display panel according to exemplary embodiments of the present disclosure.

FIG. 8 is a schematic diagram illustrating an example where a hole injection layer includes a plurality of sub-layers and a plurality of reaction layers in the embodiments of FIG. 7.

FIG. 9 is a schematic diagram of a structure of a display panel according to exemplary embodiments of the present disclosure.

FIG. 10 is a schematic diagram of a structure of a display panel according to exemplary embodiments of the present disclosure.

FIG. 11 is a flowchart illustrating a method for manufacturing a display panel according to exemplary embodiments of the present disclosure.

FIG. 12 is a flowchart illustrating a method for manufacturing a display panel according to exemplary embodiments of the present disclosure.

FIG. 13 is a flowchart illustrating a method for manufacturing a display panel according to exemplary embodiments of the present disclosure.

FIG. 14 is a flowchart illustrating a method for manufacturing a display panel according to exemplary embodiments of the present disclosure.

FIG. 15a is a graph illustrating a relationship between a current and a device efficiency of a display panel before and after being subjected to an ultraviolet irradiation treatment.

FIG. 15b is a graph illustrating a relationship between a current and a luminance of a display panel before and after being subjected to an ultraviolet irradiation treatment.

FIG. 15c is a comparison graph illustrating a relationship between a current density and a device efficiency for each of display panels with second electrode layers made of different metal materials before and after being subjected to an ultraviolet irradiation treatment.

FIG. 16 illustrates impedance spectrums of display panels with second electrode layers made of different metal materials.

FIGS. 17a to 17c are graphs illustrating device efficiency versus thickness for second sub-layers made of different materials.

FIG. 17d is a graph illustrating device efficiency versus thickness for second sub-layers made of different materials and having a same thickness.

FIG. 17e is a graph illustrating device efficiency versus thickness of a first sub-layer MoO₃.

FIG. 18a is a graph illustrating luminance versus current efficiency for a light emitting element that is not subjected to an ultraviolet irradiation treatment and light emitting elements irradiated with ultraviolet light having a wavelength of 320 nm for different durations.

FIG. 18b is a graph illustrating luminance versus current efficiency for a light emitting element that is not subjected to an ultraviolet irradiation treatment and light emitting elements irradiated with ultraviolet light having a wavelength of 365 nm for different durations.

FIG. 18c a graph illustrating luminance versus current efficiency for a light emitting element that is not subjected to an ultraviolet irradiation treatment and light emitting elements irradiated with ultraviolet light having a wavelength of 405 nm for different durations.

FIG. 18d is a graph illustrating a change of photoluminescence quantum yield of a light emitting layer with time after being subjected to an ultraviolet irradiation treatment of different wavelengths.

FIG. 19a illustrates an XPS spectrum of a 3d nuclear orbital for Mo element in a bare MoO₃ layer having a thickness of 4 nm that is not irradiated with ultraviolet light.

FIG. 19b illustrates an XPS spectrum of a 3d nuclear orbital for Mo element in a bare MoO₃ layer having a thickness of 4 nm irradiated with ultraviolet light for 3 min.

FIG. 19c illustrates an XPS spectrum of a 3d nuclear orbital for Mo element in a stack of a MoO₃ layer and a Mg:Ag alloy that is not irradiated with ultraviolet light.

FIG. 19d illustrates an XPS spectrum of a 3d nuclear orbital for Mo element in a stack of a MoO₃ layer and a Mg:Ag alloy irradiated with ultraviolet light for 1 min.

FIG. 19e illustrates an XPS spectrum of a 3d nuclear orbital for Mo element in a stack of a MoO₃ layer and a Mg:Ag alloy irradiated with ultraviolet light for 2 min.

FIG. 19f illustrates an XPS spectrum of a 3d nuclear orbital for Mo element in a stack of a MoO₃ layer and a Mg:Ag alloy irradiated with ultraviolet light for 3 min.

FIG. 20 illustrates a display apparatus provided in embodiments of the present disclosure.

FIG. 21 illustrates a display apparatus provided in embodiments of the present disclosure.

### DETAIL DESCRIPTION OF EMBODIMENTS

The exemplary embodiments are described here in detail and examples of the exemplary embodiments are illustrated in the accompanying drawings. When the following description involves the accompanying drawings, the same number in different drawings represents the same or similar elements, unless otherwise indicated. The embodiments described in the exemplary embodiments below do not represent all embodiments consistent with the present disclosure. Rather, these embodiments are merely examples of apparatus and methods consistent with certain aspects of the present disclosure, as detailed in the claims.

The terms used in the present disclosure are for the purpose of describing particular embodiments only and are not intended to limit the present disclosure. As used in the present disclosure and the claims, the singular forms “a”, “an”, and “the” are intended to include the plural forms as well, unless the context clearly indicates otherwise. It should also be understood that the term “and/or” as used herein refers to and encompasses any or all possible combinations of one or more of the associated listed items.

It is to be understood that the terms “first”, “second”, “third” and the like may be used in the present disclosure to describe various elements, but such elements should not be limited by these terms. These terms are only used to distinguish elements having a same type from another. For example, the first element may also be referred to as the second element, and similarly, the second element may also be referred to as the first element, without departing from the scope of the present disclosure. The word “if” as used herein may be interpreted as “at the time of” or “when” or “in response to a determination that”, depending on the context.

The embodiments of the present disclosure provide a display panel, a display apparatus and a corresponding manufacturing method. The display panel and the display apparatus in the embodiments of the present disclosure are described in detail below with reference to the accompanying drawings. The features in the embodiments described below may be supplemented or be combined with each other without conflict.

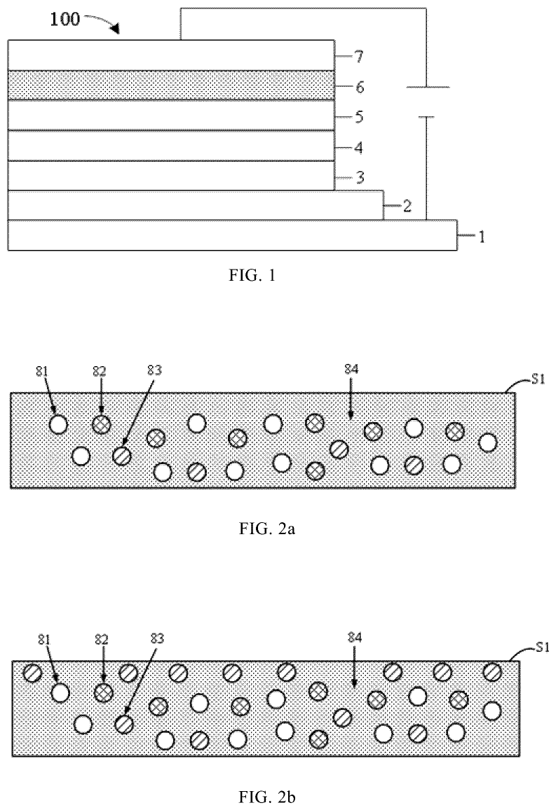

The embodiments of the present disclosure provide a display panel, which is a QLED display panel. FIG. 1 is a schematic diagram of a structure of a display panel according to some embodiments of the present disclosure. As shown in FIG. 1, a display panel 100 includes a substrate 1 and a light emitting element disposed on the substrate 1, and the light emitting element includes a first electrode layer 2, an electron transport layer 3, a light emitting layer 4, a hole transport layer 5, a hole injection layer 6, and a second electrode layer 7, which are sequentially stacked. A material of the hole injection layer 6 includes a first metal oxide and a second metal oxide, where the first metal oxide and the second metal oxide contain the same metal element, for example, the first metal oxide and the second metal oxide each include a first metal element, but an outermost electron number of the first metal element in the first metal oxide is different from that of the first metal element in the second metal oxide. That is, the valences of the first metal element in the two metal compounds are different from each other. Optionally, the valence of the first metal element in the hole injection layer 6 includes two or more of +2, +3, +4, +5, and +6. Specifically, the first metal element may be molybdenum (Mo), tungsten (W), or vanadium (V), and correspondingly, the first metal oxide may be molybdenum oxide, tungsten oxide, or vanadium oxide. It should be noted that the above oxides are merely general names. By taking the molybdenum oxide as an example, and molybdenum as a metal element may have a valence of +4 or +6, that is, in the hole injection layer 6, the first metal oxide may be molybdenum trioxide (MoO₃), and the second metal oxide may be molybdenum dioxide (MoO₂). In some embodiments, a mass of the first metal oxide in the hole injection layer 6 is greater than that of the second metal oxide.

In the related art, the material of the hole injection layer 6 includes MoO₃ having a fermi level of −5.48 eV, which is much lower than the energy level of the second electrode layer 7 (e.g., −4.2 eV). Therefore, a level barrier of an interface between the hole injection layer 6 and the second electrode layer 7 is too high, which results in the difficulty in hole injection and the too low hole transport rate in the QLED light emitting element. In the embodiments of the present disclosure, the metal M is added into the hole injection layer 6 and the metal M and the MoO₃ undergo an oxidation-reduction reaction under a certain condition, to form a third metal oxide MOy and a molybdenum dioxide MoO₂ in a lower valence state or a reduced state. In this way, a work function of the molybdenum oxide in the hole injection layer 6 can be reduced, and the reduction of the work function means an increase of the fermi level, which reduces the contact barrier of the interface between the hole injection layer 6 and the second electrode layer 7, and therefore, the interface is closer to an ohmic contact. In addition, the reduction of the valence of the Mo element in MoO₃ means an increase in the conductivity of the Mo element, and therefore electrons extracted from the hole transport layer 5 can more easily pass through the hole injection layer 6, be transported to and collected by the second electrode layer 7, which accordingly exhibit an increase in the hole injection ability.

In some embodiments, the outermost electron number of the first metal element in the first metal oxide is a, the outermost electron number of the first metal element in the second metal oxide is b, a and b are integers, and 0<a<b<8. The first metal element in the first metal oxide accounts for 40% to 50% of the total amount of the first metal element (a proportion of the first metal element in the first metal oxide in the total amount of the first metal element is in a range from 40% to 50%), and the first metal element in the second metal oxide accounts for 50% to 60% of the total amount of the first metal element. The “total amount of the first metal element” means the total amount of the first metal element in the first metal oxide and the first metal element in the second metal oxide.

In some embodiments, the first metal element in the first metal oxide is a +6 valent Mo element (a Mo element having a valence of +6), and the first metal element in the second metal oxide is a +4 valent Mo element. For example, the +6 valent Mo element accounts for 40% of the total amount of the Mo element in the hole injection layer; the +4 valent Mo element accounts for 60% of the total amount of the Mo element in the hole injection layer. For another example, the +6 valent Mo element accounts for 85.8% of the total amount of the Mo element in the hole injection layer; the +4 valent Mo element accounts for 14.2% of the total amount of the Mo element in the hole injection layer. For another example, the +6 valent Mo element accounts for 44.7% of the total amount of the Mo element in the hole injection layer; the +4 valent Mo element accounts for 55.3% of the total amount of the Mo element in the hole injection layer. For another example, the +6 valent Mo element accounts for 44.5% of the total amount of the Mo element in the hole injection layer; the +4 valent Mo element accounts for 55.5% of the total amount of the Mo element in the hole injection layer. For another example, the +6 valent Mo element accounts for 60% of the total amount of the Mo element in the hole injection layer; the +4 valent Mo element accounts for 40% of the total amount of the Mo element in the hole injection layer.

In some embodiments, referring to FIGS. 1 and 5, one of the first electrode layer 2 and the second electrode layer 7 may be an anode or a cathode, and accordingly, the other is a cathode or an anode, which may be adjusted and selected according to the type of the light emitting element. Specifically, when the light emitting element is of an inverted structure, the first electrode layer 2 is a cathode, and the second electrode layer 7 is an anode; when the light emitting device is of an upright structure, the first electrode layer 2 is an anode and the second electrode layer 7 is a cathode. The first electrode layer 2 and the second electrode layer 7 each may be a transparent electrode or an opaque electrode (a reflective electrode), and be made of a material selected from: a metal material such as aluminum, silver, gold, copper, and the like; a transparent electrode material such as indium tin oxide (ITO), fluorine-doped tin oxide (FTO), graphene, a carbon nanotube film material, and the like.

In some embodiments, the substrate 1 is a rigid substrate, and a material of the rigid substrate may be glass, metal, or the like. In other embodiments, the substrate 1 may be a flexible substrate, and a material of the flexible substrate may include one or more of PI (polyimide), PET (polyethylene terephthalate), and PC (polycarbonate).

In some embodiments, referring to FIG. 5, the hole injection layer 6 is a multi-layer structure, and includes a first sub-layer 601 and a second sub-layer 603 which are stacked, and a first reaction layer 602 disposed between the first sub-layer 601 and the second sub-layer 603. The second sub-layer 603 is located on a side of the first sub-layer 601 away from the substrate 1. A material of the first sub-layer 601 includes a first metal oxide, a material of the second sub-layer 603 includes a metal M, and a material of the first reaction layer 602 includes a second metal oxide and a third metal oxide MOy.

In some embodiments, the hole injection layer 6 further includes n third sub-layers 605 and n third reaction layers 604 sequentially and alternately disposed between the second sub-layer 603 and the second electrode layer 7, and made of different materials, the first one of the n third reaction layers 604 is close to the second sub-layer 603, and n≥0 and n is an integer.

In some embodiments, a material of each third sub-layer 605 includes a metal and a metal oxide, but is different from the metal oxide in the first sub-layer 601 and the metal element in the second sub-layer 603; a material of each third reaction layer 604 includes a metal oxide, but is different from the material in the first reaction layer 602.

In some embodiments, the materials of two adjacent third sub-layers 605 may be different from each other, the materials of two adjacent third reaction layers 604 may be different from each other, and the specific materials may be selected according to different embodiments.

In the embodiments of the present disclosure, the first metal element in the first metal oxide has a chemical activity lower than that of the metal M. The first sub-layer 601 and the second sub-layer 603 may undergo an oxidation-reduction reaction at an interface therebetween to form the first reaction layer 602. Similarly, each third reaction layer 604 is formed by an oxidation-reduction reaction of two sub-layers adjacent to the third reaction layer 604 at a contact interface therebetween. For example, the third reaction layer 604 between every two adjacent third sub-layers 605 is formed by an oxidation-reduction reaction of the two third sub-layers 605 at a contact interface therebetween; the third reaction layer 604 between the third sub-layer 605 and the second sub-layer 603 is formed by an oxidation-reduction reaction between the third sub-layer and the second sub-layer.

In some embodiments, a thickness ratio of the first sub-layer 601 and the second sub-layer 603 is in a range from 2:1 to 10:1. Specifically, the thickness of the first sub-layer 601 is in a range from 5 to 10 nm, and the thickness of the second sub-layer 603 is in a range from 1 to 5 nm. The first sub-layer 601 and the second sub-layer 603 undergo an oxidation-reduction reaction at an interface therebetween, and the thickness of the formed first reaction layer 602 is in a range from 1 nm to 2 nm. The hole injection layer 6 may be a single layer or a multi-layer structure, and has a thickness in a range from 5 nm to 31 nm.

In some embodiments, a roughness of the first reaction layer 602 is less than that of the first sub-layer 601; and a roughness of each third reaction layer 604 is less than that of each third sub-layer 605. A carrier mobility of the first reaction layer 602 is greater than that of the first sub-layer 601.

The embodiments of the present disclosure further provide a display apparatus, which may include the display panel.

The embodiments of the present disclosure further provide a method for manufacturing a display panel, including the following steps:
S10, providing a substrate 1, and sequentially forming a first electrode layer 2, an electron transport layer 3, a light emitting layer 4, a hole transport layer 5, a hole injection layer 6 and a second electrode layer 7 on the substrate 1 to form a light emitting element; the first electrode layer 2 is used as a cathode, the second electrode layer 7 is used as an anode, and the light emitting layer 4 is a quantum dot light emitting layer. A material of the hole injection layer 6 contains a first metal oxide.

In addition, the material of at least one of the hole injection layer 6 and the second electrode layer 7 includes a metal M. For example, the material of the hole injection layer 6 further contains a metal M, or the material of the second electrode layer 7 contains a metal M, or the material of the hole injection layer 6 and the material of the second electrode layer 7 both contain a metal M.
S20, applying a preset condition to the light emitting element, so that the first metal oxide and the metal M in the hole injection layer 6 undergo an oxidation-reduction reaction, thereby forming at least a second metal oxide in the hole injection layer 6; the first metal oxide and the second metal oxide each contain a first metal element, and the number of electrons in an outermost layer of the first metal element in the first metal oxide is different from the number of electrons in an outermost layer of the first metal element in the second metal oxide.

In some embodiments, a third metal oxide MOy is further formed after the oxidation-reduction reaction of the first metal oxide and the metal M.

It should be noted that the inverted light emitting element is described as an example in step S10, but the light emitting element may be an upright light emitting element in other embodiments. At this time, the first electrode layer 2, the hole injection layer 6, the hole transport layer 5, the light emitting layer 4, the electron transport layer 3, and the second electrode layer 7 are sequentially formed on the substrate 1, where the first electrode layer 2 is used as an anode and the second electrode layer 7 is used as a cathode.

In some embodiments, the preset condition may be: performing an ultraviolet irradiation treatment on the light emitting element, to promote the oxidation-reduction reaction between the first metal oxide and the metal M. A wavelength of the ultraviolet light adopted in the ultraviolet irradiation treatment is in a range from 350 nm to 410 nm, and an energy of the ultraviolet light is in a range from 0.84 J/cm² to 3 J/cm².

In some embodiments, the wavelength of the ultraviolet light adopted in the ultraviolet irradiation treatment is 350 nm, 365 nm, 405 nm, or 410 nm. An irradiation power of the ultraviolet light is 14 mW/cm², and the irradiation duration is 1 minute, 2 minutes, or 3 minutes; accordingly, the energy of the ultraviolet light is 0.84 J/cm², 1.68 J/cm², or 2.52 J/cm².

In other embodiments, the preset conditions may include: applying a certain voltage between the first electrode layer and the second electrode layer, the voltage is an operating voltage of the display panel. In this case, after the voltage is applied, the ultraviolet irradiation treatment may be performed as well, to further promote the oxidation-reduction reaction between the first metal oxide and the metal M.

When the light emitting layer 4 is a quantum dot light emitting layer, if the ultraviolet light is irradiated to the light emitting element from a side of the first electrode layer 2 away from the light emitting layer 4, the light emitting layer 4 is excited by the ultraviolet light to emit light, so that the light received by the hole injection layer 6 is no longer ultraviolet light; therefore, in order to enable the ultraviolet light to be irradiated to the hole injection layer 6, the second electrode layer 7 may be provided as a transparent electrode, and the ultraviolet light may be irradiated from a side of the second electrode layer 7 away from the first electrode layer 2. The transparent electrode herein refers to an electrode having a light transmittance of 80% or more, 85% or more, or 90% or more.

In some embodiments, the material of the second electrode layer 7 may be a magnesium-silver alloy, a mass ratio of magnesium to silver is in a range from 1:9 to 1:1, so as to ensure that the second electrode layer 7 has a high light transmittance and a good conductivity. In one example, the mass ratio of magnesium to silver is 2:8.

The first metal oxide and the metal M may be formed in various ways, such as: co-evaporating the first metal oxide and the metal M, sequentially evaporating the first metal oxide and the metal M in a layered way, and sequentially spin coating the first metal oxide and the metal M.

As described above, the hole injection layer 6 provided by the embodiments of the present disclosure includes a plurality of components, and an interface contact between the hole injection layer 6 and the second electrode layer 7 is improved by an oxidation-reduction reaction therebetween, thereby increasing a carrier transport rate at the interface. On the other hand, the metal is added into the hole injection layer 6, so that a transverse current of the hole injection layer 6 is larger. That is, the electric conduction and the heat conduction of the light emitting element are more uniform, so that the light emitting efficiency of the light emitting element is improved, the power consumption is reduced, and the service life is prolonged. Specific examples of the present disclosure will be described below by taking an example where the first metal oxide is molybdenum trioxide (MoO₃, with the Mo element being +6 valent), the second metal oxide is molybdenum dioxide (MoO₂, with the Mo element being +4 valent), the metal M is magnesium (Mg) or aluminum (Al), and the corresponding third metal oxide is magnesium oxide (MgO) or aluminum oxide (Al₂O₃).

### First Embodiment

Referring to FIG. 1, an inverted QLED display panel is adopted in the present embodiment, and includes: a substrate 1, a first electrode layer 2, an electron transport layer 3, a light emitting layer 4, a hole transport layer 5, a hole injection layer 6, and a second electrode layer 7 which are sequentially arranged. A material of the hole injection layer 6 includes a first metal oxide MoO₃ and a second metal oxide MoO₂, namely: both of the first metal oxide and the second metal oxide contain Mo, but the number of electrons in an outermost layer (an outermost electron number) of the Mo element in the first metal oxide MoO₃ is different from the number of electrons in an outermost layer (an outermost electron number) of the Mo element in the second metal oxide MoO₂. That is, valence states of the Mo element are different from each other, and +6 and +4 valences, respectively. The material of the hole injection layer 6 further includes a small amount of metal Al and a third metal oxide Al₂O₃. A mass sum of the metal Al and the third metal oxide Al₂O₃ is less than that of the first metal oxide MoO₃ and the second metal oxide MoO₂. Specifically, a proportion of the mass sum of Al and Al₂O₃ in the total mass of the hole injection layer 6 is in a range from 1% to 5%.

Referring to FIGS. 1 and 2a, the hole injection layer 6 in the present embodiment is a single-layer structure, a host material of the hole injection layer is the first metal oxide MoO₃ 84, and the metal Al 81, the third metal oxide MgO 82 and the second metal oxide MoO₂ 83 are uniformly distributed in the first metal oxide, and the four together constitute the hole injection layer 6. The metal Al and the first metal oxide MoO₃ may be co-deposited on a side of the hole transport layer 5 away from the light emitting layer 4 by co-evaporation. Under a certain condition, with reference to FIGS. 2a and 2b, the metal Al and the first metal oxide MoO₃ may undergo an oxidation-reduction reaction. Specifically, the Al loses electrons and undergoes an oxidation reaction to produce the third metal oxide Al₂O₃, and the first metal oxide MoO₃ obtains the electrons and undergoes a reduction reaction, to produce the second metal oxide MoO₂. That is, the third metal oxide MgO and the second metal oxide MoO₂ in the hole injection layer 6 are produced by a chemical reaction between the first metal oxide MoO₃ and the metal Al. In addition, the hole injection layer 6 may also be formed by co-evaporation of the metal Al, the first metal oxide MoO₃, and the second metal oxide MoO₂, which has the same principle as the above method and is not described herein again.

In this embodiment, the material of the second electrode layer 7 is Al, and in this case, the material of the second electrode layer 7 may react with the first metal oxide MoO₃, so that a concentration of the second metal oxide MoO₂ 83 is high at an interface S1 on a side of the hole injection layer 6 close to the second electrode layer 7, as shown in FIG. 2b.

In other embodiments, the metal M in the hole injection layer 6 may alternatively be Mg, and the material of the second electrode layer 7 may alternatively be Mg:Ag alloy. In this case, the host material of the hole injection layer 6 is still the first metal oxide MoO₃ 84, and the metal Mg, the third metal oxide MgO 82 and the second metal oxide MoO₂ 83 are uniformly distributed in the first metal oxide, which together constitute the hole injection layer 6. The metal Mg and the first metal oxide MoO₃ may be co-deposited on a side of the hole transport layer 5 away from the light emitting layer 4 by co-evaporation. Under a certain condition, the metal Mg and the first metal oxide MoO₃ may undergo an oxidation-reduction reaction, to form a third metal oxide MgO and a second metal oxide MoO₂. Since the second electrode layer 7 also contains Mg, the concentration of the second metal oxide MoO₂ 83 is also high at the interface S1 on a side of the hole injection layer 6 close to the second electrode layer 7.

### Second Embodiment

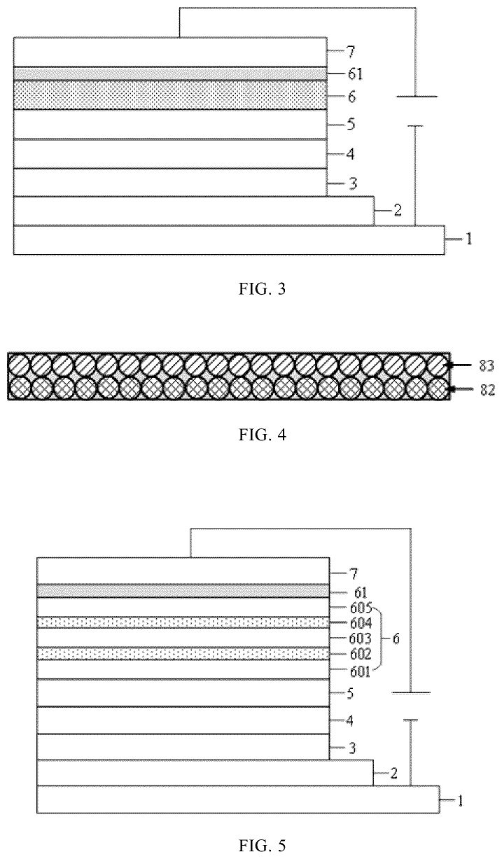

Referring to FIGS. 3 and 4, compared with the first embodiment, in this embodiment, the material of the second electrode layer 7 is Al; the metal M in the hole injection layer 6 is Mg, which undergoes an oxidation-reduction reaction with the first metal oxide MoO₃ to produce the third metal oxide MgO and the second metal oxide MoO₂. That is: the material of the hole injection layer 6 includes the first metal oxide MoO₃, the second metal oxide MoO₂, the metal Mg, and the third metal oxide MgO. Further, a second reaction layer 61 is further provided between the hole injection layer 6 and the second electrode layer 7, and a material of the second reaction layer 61 includes Al₂O₃ 83 and the second metal oxide MoO₂ 82. This is because the material of the second electrode layer 7 is Al and also undergoes an oxidation-reduction reaction with the first metal oxide MoO₃, and therefore, if the residual unreacted first metal oxide MoO₃ exists at an interface of the hole injection layer 6 close to the second electrode layer 7, the residual unreacted first metal oxide MoO₃ may undergoes an oxidation-reduction reaction with the second electrode layer 7, to form Al₂O₃ 83 and the second metal oxide MoO₂ 82, thereby forming the second reaction layer 61. A thickness of the second reaction layer 61 is in a range from 1 to 2 nm, preferably 1 nm.

### Third Embodiment

Referring to FIG. 5, the hole injection layer 6 is a multi-layer structure including a first sub-layer 601 and a second sub-layer 603, and a first reaction layer 602 disposed between the first sub-layer 601 and the second sub-layer 603. The second sub-layer 603 is located on a side of the first sub-layer 601 away from the substrate 1, a material of the first sub-layer 601 is the first metal oxide MoO₃, a material of the second sub-layer 603 is the metal Al, and correspondingly, a material of the first reaction layer 602 includes the second metal oxide MoO₂ and the third metal oxide Al₂O₃.

Further, the hole injection layer 6 further includes n third sub-layers and n third reaction layers sequentially and alternately disposed between the second sub-layer 603 and the second electrode layer 7, and made of different materials, the first one of the n third reaction layers is close to the second sub-layer 603, and n≥0 and n is an integer. Referring to FIG. 5, when n=1, the hole injection layer 6 includes one third sub-layer 605 and one third reaction layer 604.

In this embodiment, a material of the third sub-layer 605 is the same as that of the first sub-layer 601, and both of them are MoO₃. A material of the third reaction layer 604 is the same as that of the first reaction layer 602, and both of them include the second metal oxide MoO₂ and the third metal oxide Al₂O₃.

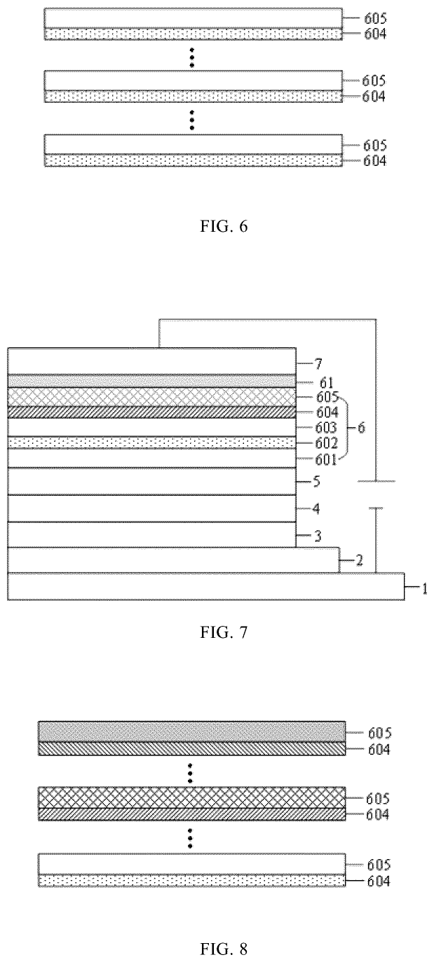

Referring to FIG. 6, in the present embodiment, the hole injection layer 6 may further include a plurality of third sub-layers 605 and a plurality of third reaction layers 604 alternately arranged one by one. Materials of the plurality of third reaction layers 604 are the same, and materials of the two adjacent third sub-layers 605 are MoO₃ and Al, respectively. The two adjacent third sub-layers 605 mean that there is no other third sub-layer 605 between the two third sub-layers 605, but there may be one third reaction layer 604 between the two third sub-layers 605.

In other embodiments, the metal M may alternatively be Mg, and the material of the second electrode layer 7 may alternatively be Mg:Ag alloy. In this case, the material of the first sub-layer 601 is the first metal oxide MoO₃, the material of the second sub-layer 603 is the metal Mg, and accordingly, the material of the first reaction layer 602 includes the second metal oxide MoO₂ and the third metal oxide MgO. As described above, the material of the third sub-layer 605 is the same as that of the first sub-layer 601, and both of them are MoO₃. The material of the third reaction layer 604 is the same as that of the first reaction layer 602, and both of them include the second metal oxide MoO₂ and the third metal oxide MgO. When the hole injection layer 6 includes a plurality of third sub-layers 605 and a plurality of third reaction layers 604, materials of the two adjacent third sub-layers 605 are MoO₃ and Mg, respectively.

### Fourth Embodiment

Referring to FIGS. 7 and 8, the present embodiment is different from the third embodiment in that materials of two adjacent third sub-layers with another third sub-layer therebetween are not exactly the same, and materials of two adjacent third reaction layers with a third reaction layer therebetween are not exactly the same. In FIG. 7, the material of the third sub-layer 605 may be WO₃, and accordingly, the material of the formed reaction layer 604 is different from the material of the first reaction layer 602.

### Fifth Embodiment

Referring to FIG. 9, an upright QLED display panel is adopted in the present embodiment, and mainly includes a substrate 1, a second electrode layer 7, a hole injection layer 6, a hole transport layer 5, an electron transport layer 3, and a first electrode layer 2, which are sequentially stacked. The hole injection layer 6 is a multi-layer structure, and includes a second sub-layer 602, a first reaction layer 603, and a first sub-layer 601 sequentially arranged in a direction away from the substrate 1. Specifically, a material of the second sub-layer 602 is the metal Al, a material of the first sub-layer 601 is MoO₃, and a material of the first reaction layer 603 includes MoO₂ and Al₂O₃. Alternatively, the material of the second sub-layer 602 is the metal Mg, the material of the first sub-layer 601 is MoO₃, and the material of the first reaction layer 603 includes MoO₂ and MgO.

### Sixth Embodiment

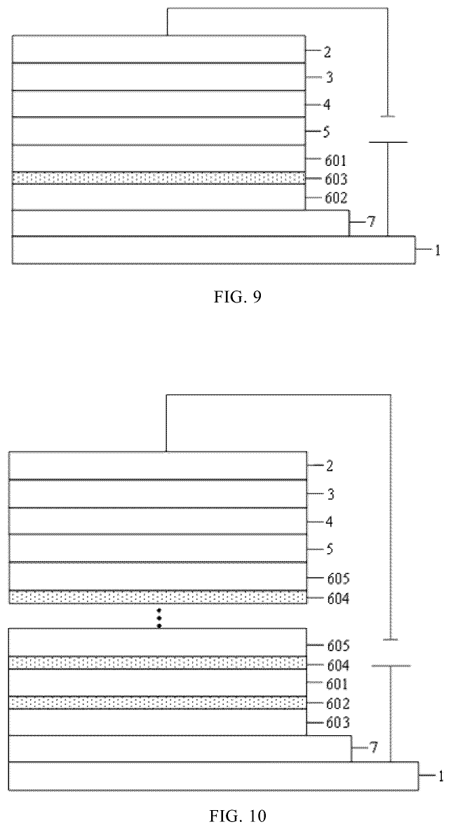

Referring to FIG. 10, compared to the fifth embodiment, the hole injection layer 6 further includes a plurality of third sub-layers 605 and a plurality of third reaction layers 604 disposed between the first sub-layer 601 and the first electrode layer 2. Materials of the sub-layers may be not identical. For example, the materials of the third sub-layers 605 may sequentially be V₂O₅, WO₃, and MoO₃.

### Seventh Embodiment

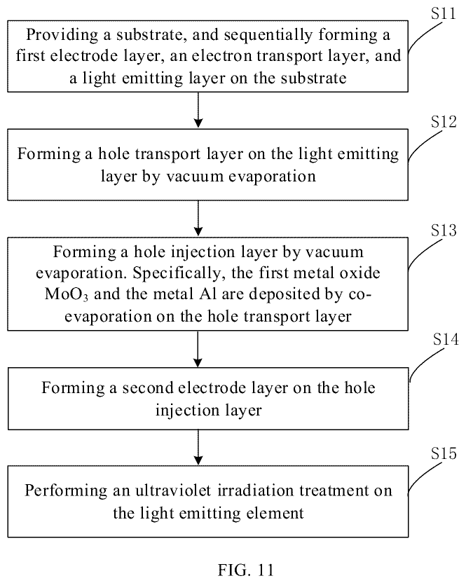

Referring to FIG. 11, the present embodiment provides a method for manufacturing an inverted OLED display panel according to the first embodiment, including the following steps:
S11: providing a substrate 1, and sequentially forming a first electrode layer 2, an electron transport layer 3, and a light emitting layer 4 on the substrate 1.
S12: forming a hole transport layer 5 on the light emitting layer 4 by vacuum evaporation under following experimental conditions: a vacuum degree less than or equal to 10⁻⁴ Pa, and an evaporation rate between 0.5 Å/s and 0.8 Å/s. The hole transport layer 5 may be made of an organic hole transport material, such as PVK (polyvinylcarbazole), TFM (poly (9,9-dioctylfluorene-CO-N-(4-butylphenyl) diphenylamine)), and TPD (N,N′-diphenyl-N,N′-Mis(3-methyllphenyl)-(1,1′-Miphenyl)-4,4-diamine) and derivatives thereof, or an inorganic hole transport material, such as nickel oxide (NiOy) and vanadium oxide (VOy). A thickness of the hole transport layer 5 is in a range from 10 nm to 60 nm.
S13: forming a hole injection layer 6 by vacuum evaporation. Specifically, the first metal oxide MoO₃ and the metal Al are deposited by co-evaporation on the hole transport layer 5 under the experimental conditions: a vacuum degree less than or equal to 10⁻⁴ Pa, and an evaporation rate between 0.1 Å/s and 0.5 Å/s. The hole injection layer 6 is a single-layer structure, where a mass percent of the metal Al is in a range from 5% to 10%;
S14: forming a second electrode layer 7 on the hole injection layer 6, thereby forming a light emitting element.
S15: performing an ultraviolet irradiation treatment on the light emitting element to cause an oxidation-reduction reaction between the first metal oxide MoO₃ and the metal Al in the hole injection layer 6, thereby forming a second metal oxide MoO₂ and a third metal oxide Al₂O₃. A mass percent of Al₂O₃ is in a range from 5% to 10%.

### Eighth Embodiment

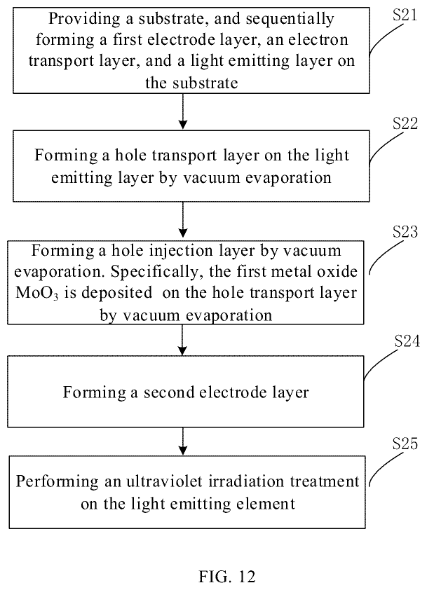

Referring to FIG. 12, the embodiment provides a method for manufacturing an inverted QLED display panel according to the first embodiment, including the following steps:
S21: providing a substrate 1, and sequentially forming a first electrode layer 2, an electron transport layer 3, and a light emitting layer 4 on the substrate 1.
S22: forming a hole transport layer 5 on the light emitting layer 4 by vacuum evaporation under following experimental conditions: a vacuum degree is less than or equal to 10⁻⁴ Pa, and an evaporation rate is between 0.5 Å/s and 0.8 Å/s. The hole transport layer 5 may be made of an organic hole transport material, such as PVK (polyvinylcarbazole), TFM (poly (9,9-dioctylfluorene-CO-N-(4-butylphenyl) diphenylamine)), and TPD (N,N′-diphenyl-N,N′-Mis(3-methyllphenyl)-(1,1′-Miphenyl)-4,4-diamine) and derivatives thereof, or an inorganic hole transport material, such as nickel oxide (NiOy) and vanadium oxide (VOy). A thickness of the hole transport layer 5 is in a range from 10 nm to 60 nm.
S23: forming a hole injection layer 6 by vacuum evaporation. Specifically, the first metal oxide MoO₃ is deposited by vacuum evaporation on the hole transport layer 5.
S24: forming a second electrode layer 7 on the hole injection layer 6, where a material of the second electrode layer 7 includes a magnesium silver alloy. A mass ratio of Mg to Ag in the magnesium silver alloy is 2:8.
S25: irradiating the hole injection layer 6 with the ultraviolet light from a side of the second electrode layer 7 away from the first electrode layer 2, to cause an oxidation-reduction reaction between the first metal oxide MoO₃ in the hole injection layer 6 and the metal Mg in the second electrode layer 7, thereby forming a second metal oxide MoO₂ and a third metal oxide MgO.

A wavelength of the ultraviolet light adopted during the ultraviolet irradiation treatment is in a range from 350 nm to 410 nm, and an energy of the ultraviolet light is between 0.84 J/cm² and 3 J/cm².

### Ninth Embodiment

This embodiment is similar to the eighth embodiment, except that when forming the hole injection layer, the first metal oxide MoO₃ and the metal Mg are deposited by co-evaporation on the hole transport layer 5 under the experimental conditions: a vacuum degree less than or equal to 10⁻⁴ Pa, and an evaporation rate between 0.1 Å/s and 0.5 Å/s. In this case, the hole injection layer 6 is irradiated with ultraviolet light in step S25, which may cause an oxidation-reduction reaction between the first metal oxide MoO₃ and the metal Mg in the hole injection layer 6 and the metal Mg in the second electrode layer 7, to form the second metal oxide MoO₂ and the third metal oxide MgO.

### Tenth Embodiment

The embodiment provides a method for manufacturing an inverted QLED display panel, where the metal M is aluminum, and a material of the second electrode layer is Al. The method in the embodiment includes the following steps:
S31: providing a substrate 1, and sequentially forming a first electrode layer 2, an electron transport layer 3, and a light emitting layer 4 on the substrate 1.
S32: forming a hole transport layer 5 on the light emitting layer 4 by vacuum evaporation under following experimental conditions: a vacuum degree less than or equal to 10⁻⁴ Pa, and an evaporation rate between 0.5 Å/s and 0.8 Å/s. The hole transport layer 5 may be made of an organic hole transport material, such as PVK (polyvinylcarbazole), TFM (poly (9,9-dioctylfluorene-CO-N-(4-butylphenyl) diphenylamine)), and TPD (N,N′-diphenyl-N,N′-Mis(3-methyllphenyl)-(1,1′-Miphenyl)-4,4-diamine) and derivatives thereof, or an inorganic hole transport material, such as nickel oxide (NiOy) and vanadium oxide (VOy). A thickness of the hole transport layer 5 is in a range from 10 nm to 60 nm.
S33: forming a hole injection layer 6 by vacuum evaporation. Specifically, the first metal oxide MoO₃ and the metal Al are deposited by co-evaporation on the hole transport layer 5 under the experimental conditions: a vacuum degree less than or equal to 10⁻⁴ Pa, and an evaporation rate between 0.1 Å/s and 0.5 Å/s. The hole injection layer 6 is a single-layer structure, and a mass percent of the metal Al is in a range from 5% to 10%;
S34: forming a second electrode layer 7 on the hole injection layer 6.
S35: applying a preset condition, so that the first metal oxide MoO₃ and the metal Al in the hole injection layer 6 undergo an oxidation-reduction reaction, to form a second metal oxide MoO₂ and a third metal oxide Al₂O₃. A mass percent of the Al₂O₃ is in a range from 1% to 5%.

In step S35, the preset condition may be: applying a certain voltage (e.g. in a range from 2V to 6V) between the first electrode layer 2 and the second electrode layer 7; or performing an ultraviolet irradiation treatment on the hole injection layer 6; or applying a certain voltage between the first electrode layer 2 and the second electrode layer 7, and then, performing an ultraviolet irradiation treatment on the hole injection layer 6. A wavelength of the ultraviolet light adopted in the ultraviolet irradiation treatment is in a range from 350 nm to 410 nm, an irradiation power is in a range from 1 mW to 100 mW, and the treatment duration is in a range from 1 min to 20 min. In one example, the energy of the ultraviolet light is between 0.84 J/cm² and 3 J/cm², for example, the irradiation power is 14 mW, and the treatment duration is 1 min, 2 min, or 3 min.

### Eleventh Embodiment

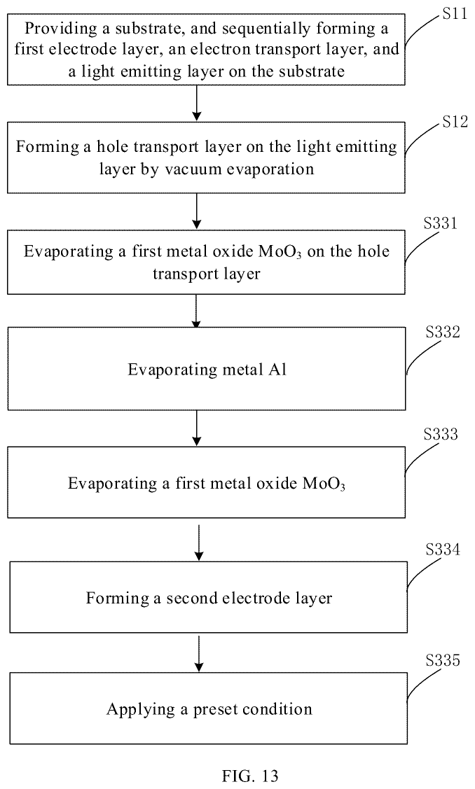

Referring to FIG. 13, compared with the seventh embodiment, in this embodiment, the hole injection layer 6 is of a multi-layer structure, and accordingly, the manufacturing method further includes the following steps:
S331: evaporating a first metal oxide MoO₃ with a thickness in a range from 1 nm to 30 nm on the formed hole transport layer 5, where the experimental conditions are as follows: a vacuum degree less than or equal to 10⁻⁴ Pa, and an evaporation rate between 0.1 Å/s and 0.5 Å/s;
S332: then, evaporating metal Al with a thickness in a range from 1 nm to 30 nm on the first metal oxide MoO₃, where the experimental conditions are as follows: a vacuum degree is less than or equal to 10⁻⁴ Pa, and an evaporation rate is between 1.2 Å/s and 2.0 Å/s.
S333: then, evaporating a first metal oxide MoO₃ with a thickness in a range from 1 nm to 30 nm on the metal Al.
S34: forming a second electrode layer 7.
S35: applying a preset condition, so that the first metal oxide MoO₃ formed in the step S331 and the metal Al formed in the step S332 undergo an oxidation-reduction reaction, to form a second metal oxide MoO₂ and a third metal oxide Al₂O₃, thereby forming a first reaction layer; and the metal Al formed in the step S332 and the first metal oxide MoO₃ formed in the step S333 undergo an oxidation-reduction reaction, to form a second metal oxide MoO₂ and a third metal oxide Al₂O₃, thereby forming a third reaction layer.

The preset condition may be: applying a certain voltage (e.g. in a range from 2V to 6V) between the first electrode layer 2 and the second electrode layer 7; or performing an ultraviolet irradiation treatment on the hole injection layer 6; or applying a certain voltage between the first electrode layer 2 and the second electrode layer 7, and then, performing an ultraviolet irradiation treatment on the hole injection layer 6. A wavelength of the ultraviolet light adopted in the ultraviolet irradiation treatment process is in a range from 350 nm to 410 nm and the energy of the ultraviolet light is between 0.84 J/cm² and 3 J/cm².

In other embodiments, the first metal oxide deposited in the step S331 is different from that in the step S333, for example: in step S331, MoO₃ is deposited, and in step S333, WO₃ is deposited, and accordingly, the first reaction layer and the third reaction layer contain different materials.

In addition, in other embodiments, the metal Al may be replaced with another metal material, such as metal Mg.

### Twelfth Embodiment Twelve

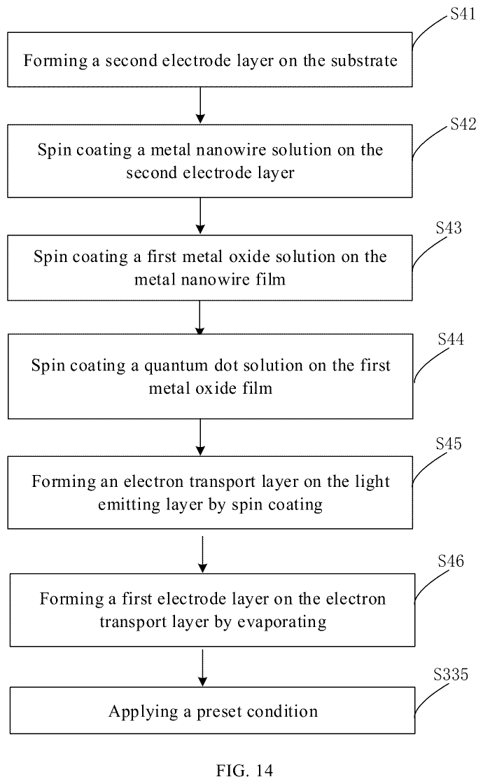

Referring to FIG. 14, the present embodiment provides a method for manufacturing an upright QLED display panel, including the following steps:
S41: forming a second electrode layer 7 on the substrate.
S42: spin coating a metal nanowire solution on the second electrode layer, to obtain a metal nanowire film with a thickness in a range from 5 nm to 10 nm; where the experimental conditions are as follows: a rotating speed is 3000 r/min and a duration is 40 s.
S43: spin coating a first metal oxide solution (e.g., a molybdenum oxide solution) on the metal nanowire film, to obtain the first metal oxide film with a thickness in a range from 5 nm to 10 nm; where the experimental conditions are as follows: a rotating speed is in a range from 2000 r/min to 3000 r/min, the duration is 40 s.
S44: spin coating a quantum dot solution on the first metal oxide film, to form a light emitting layer with a thickness in a range from 20 nm to 40 nm.
S45: forming an electron transport layer with a thickness in a range from 10 nm to 60 nm by spin coating on the light emitting layer.
S46: forming a first electrode layer with a thickness in a range from 80 nm to 120 nm by evaporating on the electron transport layer.
S47: applying a preset condition, so that the first metal oxide film formed in the step S43 and the metal nanowire film formed in the step S42 undergo an oxidation-reduction reaction at an interface therebetween, to form a first reaction layer.

The preset condition may be: applying a certain voltage (e.g. in a range from 2V to 6V) between the first electrode layer 2 and the second electrode layer 7; or performing an ultraviolet irradiation treatment on the hole injection layer 6; or applying a certain voltage between the first electrode layer 2 and the second electrode layer 7, and then, performing an ultraviolet irradiation treatment on the hole injection layer 6. A wavelength of the ultraviolet light adopted in the ultraviolet irradiation treatment process is in a range from 350 nm to 410 nm, and the energy of the ultraviolet light is between 0.84 J/cm² and 3 J/cm².

### Thirteenth Embodiment

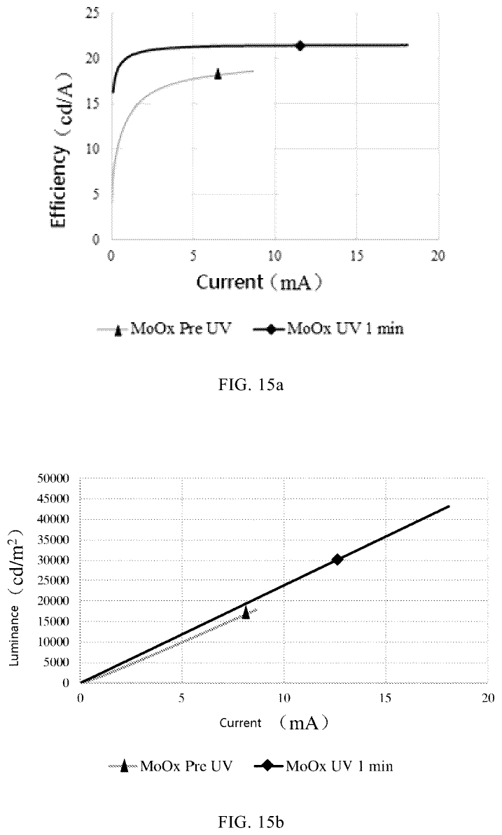

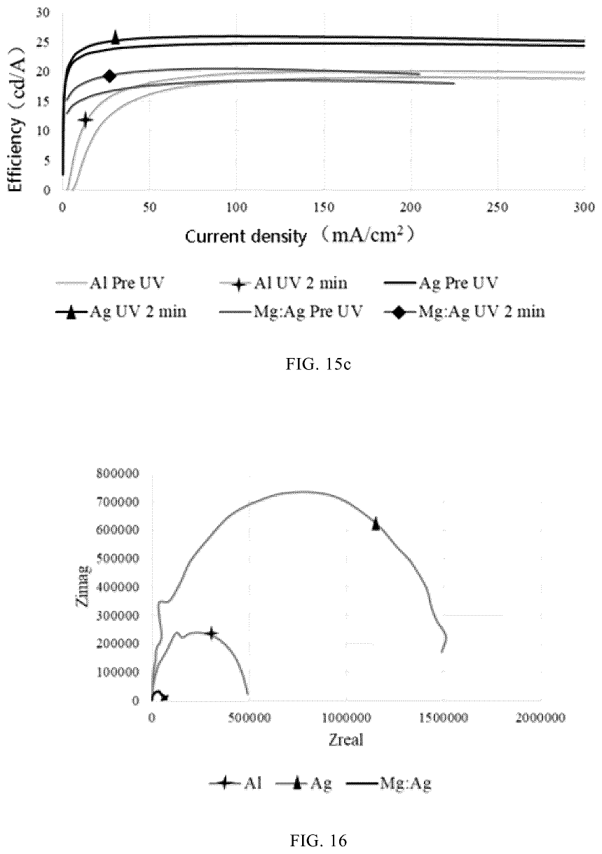

Referring to FIGS. 1 and 3, the QLED device structure described in the first embodiment or the second embodiment is adopted in the present embodiment. Specifically, the hole injection layer 6 is a single-layer structure; or the hole injection layer 6 and the second electrode layer 7 may undergo an oxidation-reduction reaction to form the second reaction layer 61. The second electrode layer 7 is a metal electrode, and the metal material may be one or more of Al, Ag, Mg:Ag. FIG. 15a is a graph illustrating a relationship between a current and a device efficiency of a display panel before and after a treatment by using the ultraviolet irradiation. FIG. 15b is a graph illustrating a relationship between a current and a luminance of a display panel before and after being subjected to an ultraviolet irradiation treatment. It can be seen from the figures that the display panel is irradiated by ultraviolet light for 1 min, so that the device efficiency is improved, and the luminance under the same current is increased. On the other hand, FIG. 15c is a comparison graph illustrating a relationship between a current density and a device efficiency for manufactured display panels with second electrode layers made of different metal materials before and after a treatment by using the ultraviolet irradiation. It can be seen from the figure that the device efficiency for each metal material is improved to a certain extent with the ultraviolet irradiation for 2 min. FIG. 16 illustrates impedance spectrums of display panels with second electrode layers made of different metal materials. It can be seen that under the same voltage, a resistance of the electrode made of Mg:Ag is the smallest and a resistance of the electrode made of Ag is the greatest, which illustrates that electrodes made of different metal materials have different effects in terms of the current and the device efficiency.

### Fourteenth Embodiment

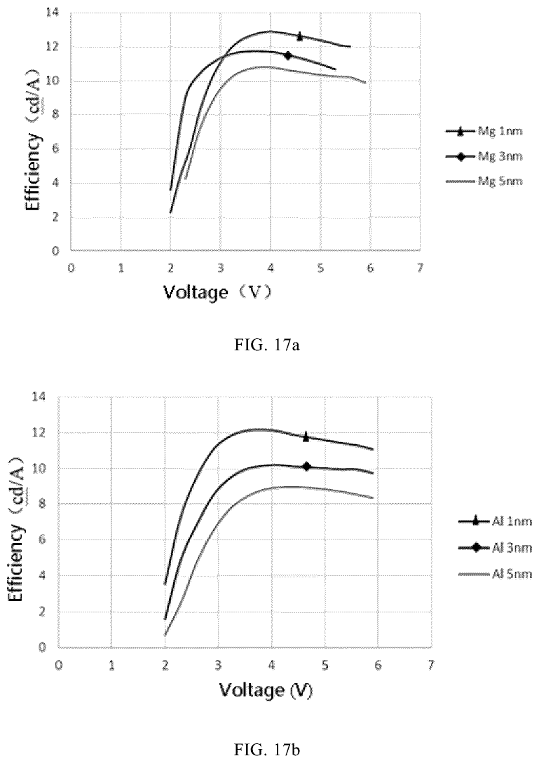

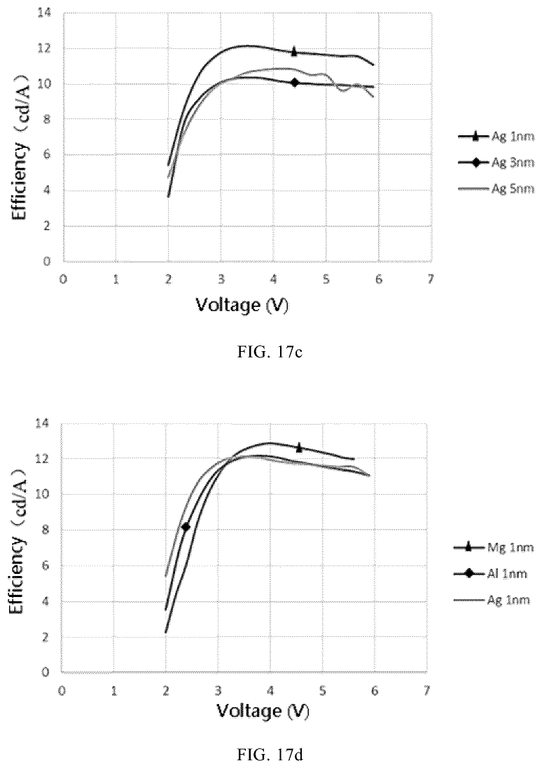

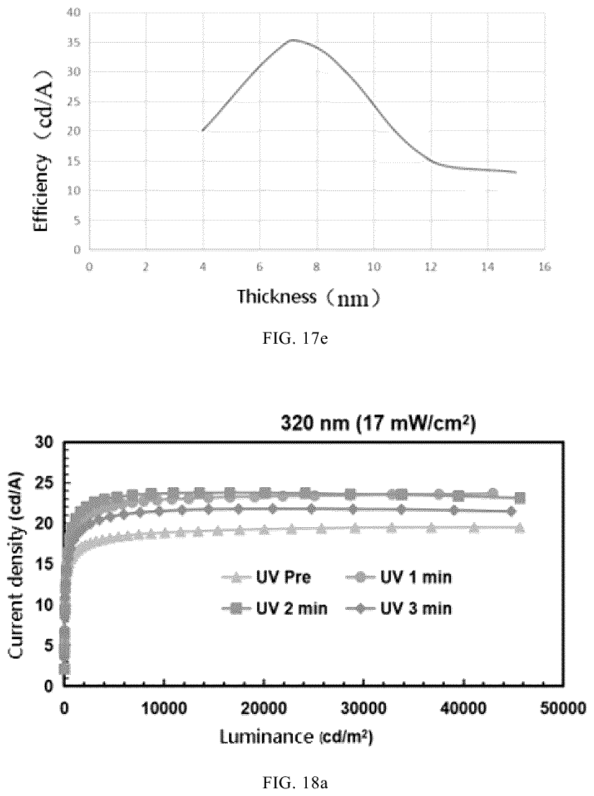

Referring to FIGS. 5 and 8, the QLED display panel described in the third embodiment or the fifth embodiment is adopted in the present embodiment. Specifically, the hole injection layer 6 is a multi-layer structure, and includes: the first sub-layer 601, the first reaction layer 602 and the second sub-layer 603, where the material of the first sub-layer 601 is MoO₃, the material of the second sub-layer 603 is any one of Mg, Al and Mg, and a thickness of the first sub-layer 601 is in a range from 1 nm to 10nm, preferably 5 nm. A thickness of the second sub-layer 603 is in a range from 1 nm to 10 nm, specifically, 1 nm, 3 nm, or 5 nm. FIGS. 17a to 17c are graphs illustrating device efficiency versus thickness with second sub-layers 603 made of different materials, with voltage (in volts, V) on the abscissa and device efficiency (in candelas/amps, cd/A) for the display panel on the ordinate. Experimental results show that the device efficiency exhibits a tendency of increasing and then decreasing when the voltage is increased from 2V to 6V, and in addition, the device efficiency is inversely proportional to the thickness of the second sub-layer 603, i.e., the device efficiency decreases as the thickness of the second sub-layer 603 increases, so the device efficiency is highest when the thickness of the second sub-layer 603 is 1 nm. Referring to FIG. 17d, at a thickness of 1 nm, the device efficiency is relatively higher when the second sub-layer 603 is made of Mg. FIG. 17e is a graph of device efficiency versus thickness of a first sub-layer MoO₃, with thickness (in nanometers, nm) on the abscissa and device efficiency (in candelas/amps, cd/A) on the ordinate. Experimental results show that when the thickness of the first sub-layer is in a range from 5 nm to 7 nm, the device efficiency is relatively higher.

### Fifteenth Embodiment

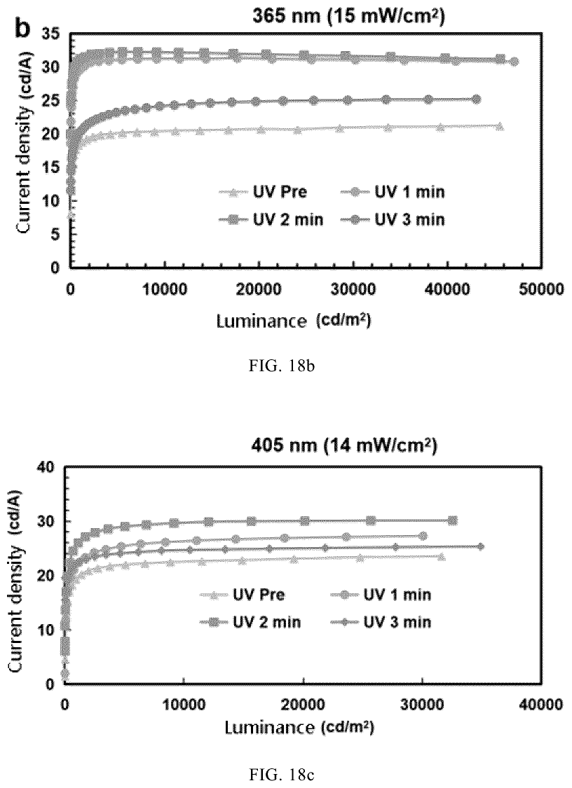

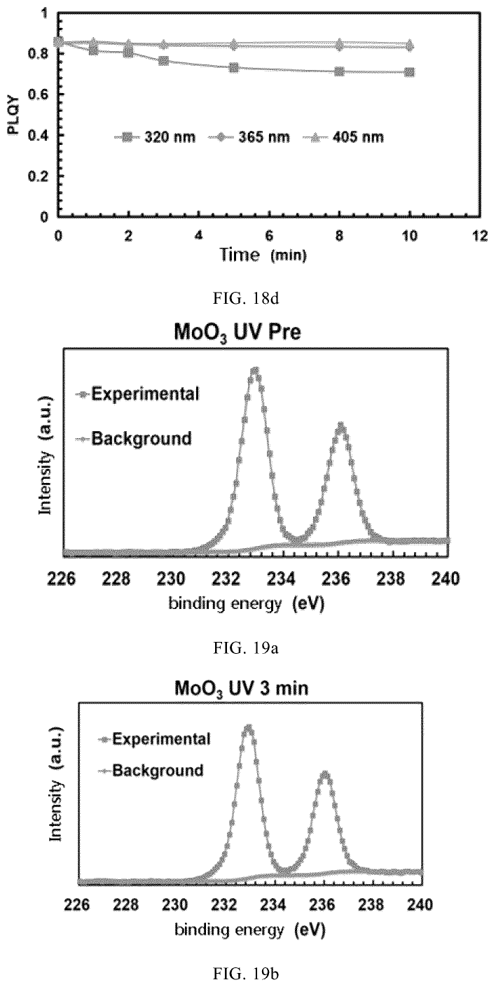

In this embodiment, the display panel is manufactured by the manufacturing method in the seventh embodiment. Ultraviolet irradiation treatments with different wavelengths and different duration are performed in step S5. FIG. 18a is a graph illustrating luminance versus current efficiency for a light emitting element that is not subjected to an ultraviolet irradiation treatment and light emitting elements irradiated with ultraviolet light having a wavelength of 320 nm for different durations. FIG. 18b is a graph illustrating luminance versus current efficiency for a light emitting element that is not irradiated with ultraviolet light and light emitting elements irradiated with ultraviolet light having a wavelength of 365 nm for different durations. FIG. 18c a graph illustrating luminance versus current efficiency for a light emitting element that is not irradiated with ultraviolet light and light emitting elements irradiated with ultraviolet light having a wavelength of 405 nm for different durations. FIG. 18d is a graph illustrating a change of photoluminescence quantum yield (PLQY) of a light emitting layer with time after irradiation with ultraviolet light of different wavelengths. In FIGS. 18a to 18d, “UV Pre” indicates that the light emitting element is not irradiated with ultraviolet light, “UV 1 min” indicates that the light emitting element is irradiated with ultraviolet light for 1 min, “UV 2 min” indicates that the light emitting element is irradiated with ultraviolet light for 2 min, and “UV 3 min” indicates that the light emitting element is irradiated with ultraviolet light for 3 min. Further, an irradiation power is 17 mW/cm² when the light emitting element is irradiated with ultraviolet light at a wavelength of 320 nm; an irradiation power is 15 mW/cm² when the light emitting element is irradiated with ultraviolet light at a wavelength of 365 nm; an irradiation power is 14 mW/cm² when the light emitting element is irradiated with ultraviolet light at a wavelength of 405 nm.

As can be seen from FIGS. 18a to 18d, the efficiency of the light emitting element is improved after the ultraviolet irradiation treatment is performed on the light emitting element. As shown in FIG. 18b, the current efficiency is increased from 19 cd/A to 33.2 cd/A when the light emitting element is irradiated with ultraviolet light at a wavelength of 365 nm for 2 min, and then is decreased to about 24 cd/A when the light emitting element is irradiated with the ultraviolet light for 3 min. As shown in FIG. 18c, the current efficiency reaches the maximum value of 31 cd/A when the light emitting element is irradiated with ultraviolet light at a wavelength of 405 nm for 2 min. The current efficiency reaches 27 cd/A when the light emitting element is irradiated with ultraviolet light at a wavelength of 405 nm for 3 min, which is better than the effect of irradiating the light emitting element with the ultraviolet light at a wavelength of 365 nm for 3 min. In order to determine the reasons for the difference among the effects of irradiation with the ultraviolet light at different wavelengths, the inventors measure the change in PLQY of the light emitting layer after the light emitting element is irradiated with ultraviolet light in a nitrogen atmosphere. As shown in FIG. 18d, when the light emitting element is irradiated with ultraviolet light at a wavelength of 405 nm for 10 minutes, the PLQY of the light emitting layer hardly changed. When the light emitting element is irradiated with ultraviolet light at a wavelength of 365 nm, the PLQY of the light emitting layer slightly decreases as the irradiation duration increases. When the light emitting element is irradiated with ultraviolet light at a wavelength of 320 nm, the PLQY of the light emitting layer slightly decreases as the irradiation duration increases. When the light emitting element is irradiated with ultraviolet light at a wavelength of 320 nm for 10 minutes, the PLQY of the light emitting layer slightly decreases to about 82% of the initial value, which indicates that the performance of the light emitting layer is decreased after irradiation with ultraviolet light at a short wavelength. By comparing the current efficiency and the PLQY of irradiation with ultraviolet light at three different wavelengths for different durations, it is apparent that the ultraviolet light at a wavelength of 405 nm has a positive influence on the light emitting element, and the ultraviolet light at a shorter wavelength is not suitable for the light emitting element, and the current efficiency is reduced as the ultraviolet irradiation duration increases.

### Sixteenth Embodiment

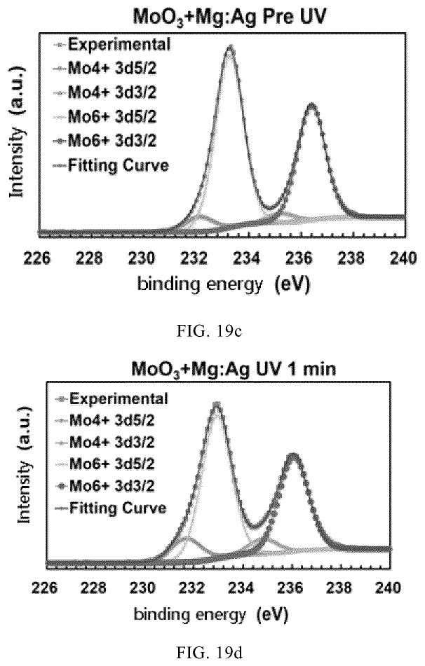

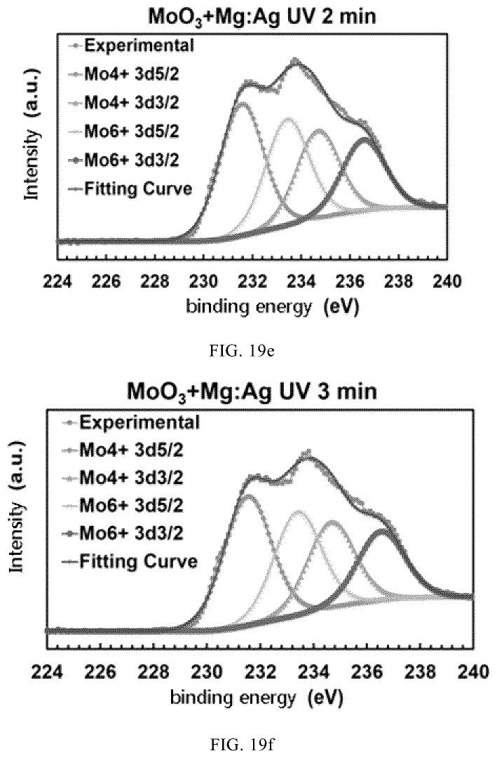

In this embodiment, X-ray photon (XPS) spectra of Mo element under different conditions are detected. FIG. 19a illustrates an XPS spectrum of a 3d nuclear orbital for Mo element in a bare MoO₃ layer, having a thickness of 4 nm, which is not irradiated with ultraviolet light. FIG. 19b illustrates an XPS spectrum of a 3d nuclear orbital for Mo element in a bare MoO₃ layer, having a thickness of 4 nm, irradiated with ultraviolet light for 3 min. FIG. 19c illustrates an XPS spectrum of a 3d nuclear orbital for Mo element in a stack of a MoO₃ layer and a Mg:Ag alloy that is not irradiated with ultraviolet light. FIG. 19d illustrates an XPS spectrum of a 3d nuclear orbital for Mo element in a stack of a MoO₃ layer and a Mg:Ag alloy irradiated with ultraviolet light for 1 min. FIG. 19e illustrates an XPS spectrum of a 3d nuclear orbital for Mo element in a stack of a MoO₃ layer and a Mg:Ag alloy irradiated with ultraviolet light for 2 min. FIG. 19f illustrates an XPS spectrum of a 3d nuclear orbital for Mo element in a stack of a MoO₃ layer and a Mg:Ag alloy irradiated with ultraviolet light for 3 min. In the stack of the MoO₃ layer and the Mg:Ag alloy layer, a thickness of the MoO₃ layer is 10 nm, and a thickness of the Mg:Ag alloy layer is 1 nm. At the time of ultraviolet irradiation, an initial angle θ=90°, and θ represents the angle of X-ray at the time of testing XPS. In FIGS. 19a to 19f, “experimental” represents a test curve, and “background” represents a curve in an environmental background in the absence of the material; “Fitting curve” represents a curve with the tested experimental data subjected to the software fitting.

As shown in FIGS. 19a and 19b, two peaks are observed around 236.5 eV and 233.2 eV, and are assigned to Mo⁶⁺3d_{3/2} and Mo⁶⁺3d_{5/2}, respectively. When the irradiation lasts for 3 min, no other peaks appear. It can be demonstrated that the valence state of Mo in the MoO3 layer is not changed by ultraviolet light. On the other hand, in addition to the two peaks, a shoulder is observed around 228 eV to 234 eV in the XPS spectrum as shown in FIG. 19c. Curve fitting calculations show that the XPS spectrum is subjected to a de-convolution, to form four peaks at positions around 236.5 eV, 235.1 eV, 233.2 eV and 232.0 eV, respectively. The peaks at positions around 236.5 eV and 233.2 eV are assigned to Mo⁶⁺3d_{3/2} and Mo⁶⁺3d_{5/2}, respectively, and the peaks at positions around 235.1 eV and 232.0 eV are assigned to Mo⁴⁺3d_{3/2} and Mo⁴⁺3d_{5/2}, respectively.

Table 1 is a statistical table of peak areas of different valence states of the Mo element obtained by the XPS spectrum, where the proportion of the peak areas of different valence states represents the content ratio of the element of different valence states.

| | MoOₓ + | MoOₓ + | MoOₓ + | MoOₓ + |
|---|---|---|---|---|
| | Mg:Ag | Mg:Ag | Mg:Ag | Mg:Ag |
| | UV Pre | UV 1 min | UV 2 min | UV 3 min |
| | (% area) | (% area) | (% area) | (% area) |
| Mo⁶⁺3d_{3/2} | 36.86 | 34.31 | 17.86 | 17.78 |
| Mo⁶⁺3d_{5/2} | 55.29 | 51.46 | 26.81 | 26.69 |
| Mo⁴⁺3d_{3/2} | 4.71 | 8.54 | 33.21 | 33.33 |
| Mo⁴⁺3d_{5/2} | 3.14 | 5.69 | 22.12 | 22.2 |

The effect of the ultraviolet irradiation on the interface between the Mg:Ag alloy layer and the MoO₃ layer can be seen from FIGS. 19d to 19f and table 1. An oxidation state of the stack of the Mg:Ag alloy layer and the MoO₃ layer when the stack is irradiated by ultraviolet light for 2 min is lower than that of the stack when the stack is irradiated by ultraviolet light for 1 min. As the ultraviolet irradiation duration is extended to 2 min, the relative peak areas assigned to Mo⁶⁺3d_{3/2} and Mo⁶⁺3d_{5/2} are respectively decreased from 36.86% to 17.78% and from 55.29% to 26.69%, and the relative peak areas assigned to Mo⁴⁺3d_{3/2} and Mo⁴⁺3d_{5/2} are respectively increased from 4.71% to 33.33% and from 3.14% to 22.2%. As the ultraviolet irradiation duration is extended to 2 min from 3 min, all peak areas hardly changed. Therefore, the oxidation-reduction reaction occurs only at the interface between the MoO₃ layer and the Mg:Ag alloy layer, and MoO₃ farther from the Mg:Ag alloy layer is not changed further. These results indicate that MoOx (x<3) is formed by ultraviolet irradiation at the interface between the MoO₃ layer and the Mg:Ag alloy layer. The reduction of the valence state of the Mo element means the improvement of the conductivity of the Mo element, and therefore, the interface is closer to an ohmic contact, thereby improving the hole injection effect in the light emitting element.

### Seventeenth Embodiment

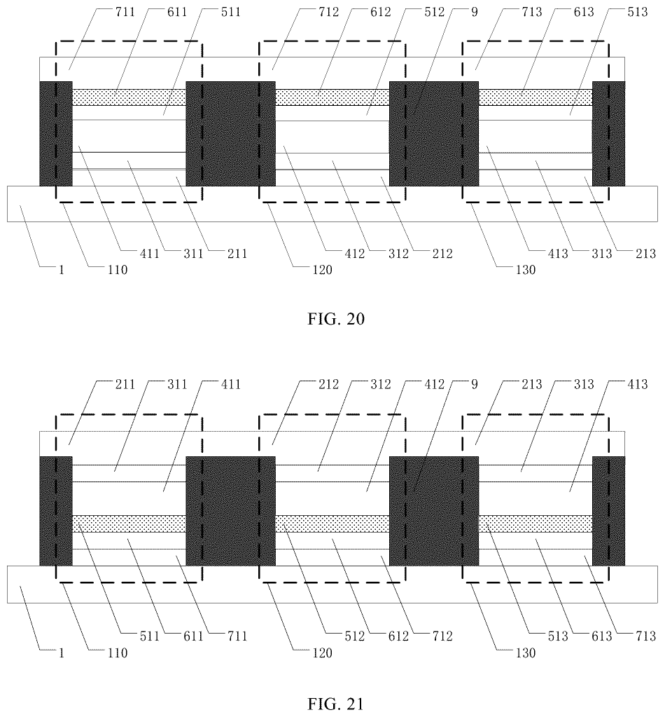

Referring to FIGS. 20 and 21, the overall structure of the inverted QLED display panel and the overall structure of the upright QLED display panel are shown, respectively. Referring to FIG. 20, the inverted QLED display panel includes a first light emitting element 110, a second light emitting element 120, and a third light emitting element 130, which may be configured to emit light of different colors. In some embodiments, the first light emitting element 110 may emit red light, the second light emitting element 120 may emit green light, and the third light emitting element 130 may emit blue light. The first light emitting element 110 includes a first electrode layer 211, a first electron transport layer 311, a first light emitting layer 411, a first hole transport layer 511, a first hole injection layer 611, and a second electrode layer 711; the second light emitting element 120 includes: a first electrode layer 212, a second electron transport layer 312, a second light emitting layer 412, a second hole transport layer 512, a second hole injection layer 612, and a second electrode layer 712; the third light emitting element 130 includes: a first electrode layer 213, a third electron transport layer 313, a third light emitting layer 413, a third hole transport layer 513, a third hole injection layer 613, and a second electrode layer 713. The first electrode layer 211 is provided to be in contact with the electron transport layer in each light emitting element, and the first electrode layer 211 is configured to provide electrons when the light emitting element emits light.

In the inverted QLED display panel, the electron transport layer is located on a side of the light emitting layer close to the substrate 1, and in the upright QLED display panel, the electron transport layer is located on a side of the light emitting layer away from the substrate 1.

In some examples, the first light emitting layer 411 may be a red quantum dot light emitting layer, and a material of the first light emitting layer 411 may include a cadmium selenide (CdSe) or CdSe/ZnS core-shell quantum dot material; or a cadmium-free quantum dot material, such as an indium phosphide (InP) or InP/ZnS core-shell quantum dot material, to reduce environmental pollution.

In some examples, the display apparatus may be any product or component having a display function, such as a smart phone, a tablet computer, a television, a display, a notebook computer, a digital photo frame, or a navigator or the like.

It is noted that in the drawings, sizes of layers and regions may be exaggerated for clarity of illustration. Also, it will be understood that when an element or layer is referred to as being located “on” another element or layer, it may be directly on the other element or intervening layers may be present therebetween. In addition, it will be understood that when an element or layer is referred to as being located “under” another element or layer, it may be directly under the other element or more than one intervening layer or element may be present therebetween. In addition, it will also be understood that when a layer or element is referred to as being located “between” two layers or elements, it may be the only layer between the two layers or elements, or more than one intermediate layer or element may also be present between the two layers or elements. Like reference numerals refer to like elements throughout.

Other embodiments of the present disclosure will be apparent to one of ordinary skill in the art from consideration of the specification and practice of the present disclosure. The present disclosure is intended to cover any variations, uses, or adaptations of the present disclosure following the general principle of the present disclosure and including the common general knowledge or the common technical means in the art not disclosed by the present disclosure. It is intended that the specification and examples are considered as exemplary only, with a true scope and spirit of the present disclosure being indicated by the claims.

It will be understood that the present disclosure is not limited to the precise arrangements that have been described above and shown in the drawings, and that various modifications and changes may be made without departing from the scope thereof. The scope of the present disclosure is limited only by the claims.

1. A display panel, comprising: a first electrode layer, an electron transport layer, a light emitting layer, a hole transport layer, a hole injection layer, and a second electrode layer, which are sequentially stacked;
wherein a material of the hole injection layer comprises a first metal oxide and a second metal oxide, the first metal oxide and the second metal oxide each comprise a first metal element, and an outermost electron number of the first metal element in the first metal oxide is different from an outermost electron number of the first metal element in the second metal oxide.

2. The display panel according to claim 1, wherein the outermost electron number of the first metal element in the first metal oxide is a, the outermost electron number of the first metal element in the second metal oxide is b, and 0<a<b<8; and
the first metal element in the first metal oxide accounts for 40% to 50% of a total amount of the first metal element, and the first metal element in the second metal oxide accounts for 50% to 60% of the total amount of the first metal element.

3. The display panel according to claim 1, wherein the material of the hole injection layer further comprises a metal M and a third metal oxide MOy, 0<y≤3, y being a natural number or a decimal; and wherein a mass sum of the metal M and the third metal oxide Moy is less than that of the first metal oxide and the second metal oxide.

4. (canceled)

5. The display panel according to claim 3, wherein a mass ratio of the metal M to the third metal oxide MOy is in a range from 3:1 to 5:1.

6. The display panel according to claim 5, wherein a mass percent of the metal M in the hole injection layer is in a range from 5% to 10%; and a mass percent of the third metal oxide MOy in the hole injection layer is in a range from 1% to 5%.

7. The display panel according to claim 5, wherein the hole injection layer comprises a first sub-layer and a second sub-layer, and a first reaction layer between the first sub-layer and the second sub-layer which are stacked together; a material of the first sub-layer comprises the first metal oxide, a material of the second sub-layer comprises the metal M, and a material of the first reaction layer comprises the second metal oxide and the third metal oxide MOy.

8. The display panel according to claim 7, wherein the hole injection layer further comprises n third sub-layers and n third reaction layers alternately arranged between the second sub-layer and the second electrode layer, and made of different materials; every one third sub-layer and one third reaction layer form a pair; the third reaction layer in each pair is closer to the second sub-layer than the third sub-layer in the pair, and n≥0 and n is an integer.

9. The display panel according to claim 8, wherein a material of each third sub-layer comprises a metal and a metal oxide, and is different from a material of the first sub-layer and a material of the second sub-layer; a material of each third reaction layer comprises a metal oxide and is different from a material of the first reaction layer.

10. The display panel according to claim 9, wherein the n third sub-layers are made of different materials and the n third reaction layers are made of different materials.

11. The display panel according to claim 8, wherein the first reaction layer has a roughness less than that of the first sub-layer; and each third reaction layer has a roughness less than that of each third sub-layer; and
a metal element in the first metal oxide has a chemical activity lower than that of the metal M.

12-13. (canceled)

14. The display panel according to claim 3, wherein the metal element in the first metal oxide comprises at least one of molybdenum, vanadium, and tungsten; and
wherein the metal M comprises at least one of magnesium, aluminum, copper, and silver.

15-16. (canceled)

17. The display panel according to claim 7, wherein a thickness ratio of the first sub-layer to the second sub-layer is in a range from 2:1 to 10:1.

18. The display panel according to claim 17, wherein the first sub-layer has a thickness in a range from 5 nm to 10 nm, the second sub-layer has a thickness in a range from 1 nm to 5 nm, and the first reaction layer has a thickness in a range from 1 nm to 2 nm; and
wherein the hole injection layer has a thickness in a range from 5 nm to 31 nm.

19. The display panel according to claim 7, wherein the first reaction layer has a carrier mobility greater than that of the first sub-layer.

20. (canceled)

21. A display apparatus, comprising the display panel according to claim 1.

22. A method for manufacturing a display panel, comprising:
providing a substrate, and sequentially forming a first electrode layer, an electron transport layer, a light emitting layer, a hole transport layer, a hole injection layer and a second electrode layer on the substrate, to form a light emitting element; wherein a material of the hole injection layer comprises a first metal oxide; a material of at least one of the hole injection layer and the second electrode layer comprises a metal M; and
applying a preset condition to the light emitting element, so that the first metal oxide and the metal M undergo an oxidation-reduction reaction, thereby forming at least a second metal oxide in the hole injection layer; wherein the first metal oxide and the second metal oxide each contain a first metal element, and an outermost electron number of the first metal element in the first metal oxide is different from an outermost electron number of the first metal element in the second metal oxide.

23. The method for manufacturing a display panel according to claim 22, wherein the preset condition comprises: applying a voltage between the first electrode layer and the second electrode layer, wherein the voltage is an operating voltage of the display panel.

24. The method for manufacturing a display panel according to claim 22, wherein the preset condition comprises: performing an ultraviolet irradiation treatment on the light emitting element, wherein ultraviolet light used in the ultraviolet irradiation treatment has a wavelength in a range from 350 nm to 410 nm, and an energy between 0.84 J/cm² and 3 J/cm².

25. The method for manufacturing a display panel according to claim 22, wherein the forming the hole injection layer comprises: depositing the first metal oxide and the metal M on the hole transport layer by co-evaporation.

26. The method for manufacturing a display panel according to claim 22, wherein the forming the hole injection layer comprises:
depositing the metal M on the hole transport layer by spin coating, wherein the metal M is a metal nanowire; and
depositing the first metal oxide on the metal M at a side away from the hole transport layer by spin coating.
